(19) United States
(12) Patent Application Publication
(10) Pub. No.: US 2026/0206331 A1
(43) Pub. Date: Jul. 16, 2026

(54) ENCAPSULANT FILM AND PHOTOVOLTAIC MODULE COMPRISING THE SAME

(71) Applicant: Amcor Flexibles North America, Inc., Neenah, WI (US)

(72) Inventors: Peter Ettridge, Worcester (GB); Erik Bogels, Lanaken (BE)

(21) Appl. No.: 19/561,241

(22) Filed: Mar. 9, 2026

Related U.S. Application Data
(63) Continuation of application No. 18/860,574, filed on May 24, 2022.

(51) Int. Cl. H10F 19/80; B32B 7/027; B32B 9/04; B32B 27/32

(52) U.S. Cl. CPC H10F 19/804; B32B 7/027; B32B 9/045; B32B 27/32; B32B 2307/306; B32B 2307/7376; B32B 2457/12

(57) ABSTRACT

An encapsulant film for a photovoltaic module includes an encapsulating layer and a heat resistant layer disposed adjacent to the encapsulating layer. The encapsulating layer includes polyethylene in an amount of 50% to 100%, by weight. The heat resistant layer includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

### TECHNICAL FIELD

The present application relates generally to an encapsulant film for a photovoltaic module, a photovoltaic module including the encapsulant film, and a method of manufacturing the photovoltaic module.

### BACKGROUND

Photovoltaic modules are widely used for generating electricity from sunlight. Photovoltaic modules may be produced using Hetero Junction Technology (HJT) and Smart Wire Connection Technology (SWCT) in order to improve cost and performance efficiency as compared to conventional busbar technology.

A photovoltaic module produced using HJT and SWCT typically includes a plurality of conductors (e.g., electrical wires) that connect multiple photovoltaic layers together, and a transparent film to encapsulate and secure the conductors on the photovoltaic layers.

One example of the transparent film that is currently used includes an unmodified polyethylene (PE). However, the plurality of conductors may burn through the unmodified polyethylene during manufacture of the photovoltaic module. Furthermore, use of the unmodified polyethylene may allow shear stresses to be transmitted to an interface between the photovoltaic layers and the plurality of conductors during vacuum lamination and/or due to thermal cycling during service. Another example of the transparent film that is currently used includes a PET/LDPE (polyethylene terephthalate/low-density polyethylene) structure. However, PET may block ultraviolet light, thereby reducing an efficiency of the photovoltaic module.

### SUMMARY

An encapsulant film for a photovoltaic module has been developed. The encapsulant film may provide a reliable bonding of a plurality of conductors to a photovoltaic layer of the photovoltaic module. In other words, the encapsulant film may have an improved dimensional stability, such that the plurality of conductors may be securely disposed on the photovoltaic layer during manufacture of photovoltaic module. Further, the encapsulant film may prevent the plurality of conductors from burning therethrough during manufacture of the photovoltaic module and during operation of the photovoltaic module. Additionally, the encapsulant film may provide dimensional stability allowing for more reliable electrical connection between the plurality of the conductors and the photovoltaic module. The encapsulant film may be substantially transparent to UV light, visible light, and IR light, thereby improving an efficiency of the photovoltaic module during operation.

One embodiment of the present disclosure is an encapsulant film for a photovoltaic module. The encapsulant film includes an encapsulating layer including polyethylene in an amount of 50% to 100%, by weight. The encapsulant film further includes a heat resistant layer disposed adjacent to the encapsulating layer. The heat resistant layer includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

During manufacture of the photovoltaic module, the encapsulating layer may bond to a plurality of conductors and to a photovoltaic layer of the photovoltaic module. Specifically, during lamination of the encapsulant film, the encapsulating layer may soften, flow, and form around the plurality of conductors.

The heat resistant layer may provide dimensional stability to the encapsulating layer during manufacture of the photovoltaic module and during operation of the photovoltaic module. Further, the heat resistant layer may prevent the plurality of conductors from burning through the encapsulant film during manufacture of the photovoltaic module and during operation of the photovoltaic module. The heat resistant layer may further provide additional properties to the encapsulant film, such as barrier properties, anti-corrosive properties, UV resistance, and the like.

In some embodiments, the polyethylene of the encapsulating layer is modified with one of maleic anhydride, carboxylic acid, methacrylic acid, acrylic acid, acrylate, and glycidyl methacrylate in an amount of 0.01% to 9%, by weight of the encapsulating layer. Modification of the polyethylene of the encapsulating layer may improve, for example, flow and/or adhesion characteristics of the encapsulating layer upon being heated.

In some embodiments, the polyethylene of the encapsulating layer includes at least one of ultra-low-density polyethylene, low density polyethylene, linear low-density polyethylene, medium density polyethylene, linear medium density polyethylene, metallocene low density polyethylene, high density polyethylene, ethylene vinyl acetate, ethylene acrylate, ethylene acrylic acid, and methacrylic acid copolymer.

In some embodiments, the encapsulating layer includes a thickness from 5 microns to 100 microns.

In some embodiments, the heat resistant layer includes a thickness from 1.5 microns to 30 microns.

In some embodiments, the heat resistant layer includes a glass transition temperature (Tg) of more than 85 °C, and preferably more than 140 °C.

In some embodiments, the heat resistant layer includes a glass transition temperature (Tg) of more than 20 °C. The heat resistant layer further includes a melting temperature (Tm) of more than 85 °C, and preferably more than 140 °C.

The glass transition temperature and/or the melting temperature of more than 140 °C may enable the heat resistant layer to provide dimensional stability to the encapsulating layer during manufacture of the photovoltaic module and during operation of the photovoltaic module, and further prevent the plurality of conductors from burning through the encapsulant film during manufacture of the photovoltaic module and during operation of the photovoltaic module.

In some embodiments, for an incident light having a wavelength greater than 280 nanometers, the encapsulant film transmits at least 80% of the incident light. In other words, in some embodiments, the encapsulant film may be substantially transparent to light having an ultraviolet wavelength, a visible light wavelength, and/or an infrared wavelength. Therefore, the encapsulant film may improve an efficiency of the photovoltaic module.

In some embodiments, the encapsulant film further includes a first tie layer disposed between the encapsulating layer and the heat resistant layer. The first tie layer bonds the heat resistant layer to the encapsulating layer.

In some embodiments, the encapsulant film further includes a secondary layer disposed opposite to the encapsulating layer and adjacent to the heat resistant layer. The secondary layer includes polyethylene in an amount of 50% to 100%, by weight.

The secondary layer may act as a primer and improve an adhesion of a bulk encapsulant layer (that encapsulates the encapsulant film) with the encapsulant film. The secondary layer may also help to disperse stress related forces originating from dimensional changes of the bulk encapsulant layer during manufacturing and operation of the photovoltaic module.

In some embodiments, the polyethylene of the secondary layer is modified with one of maleic anhydride, carboxylic acid, methacrylic acid, acrylic acid, acrylate, and glycidyl methacrylate in an amount of 0.01% to 9%, by weight of the secondary layer. Modification of the polyethylene of the secondary layer may improve, for example, adhesion characteristics of the secondary layer upon being heated.

In some embodiments, the secondary layer includes a thickness from 5 microns to 100 microns.

In some embodiments, the encapsulating layer, the heat resistant layer, and the secondary layer are coextruded together.

The encapsulating layer, the heat resistant layer, and the secondary layer may provide a symmetrical structure to the encapsulant film. The symmetrical structure may reduce or prevent curling of the encapsulant film, thereby facilitating processing of the encapsulant film.

In some embodiments, the encapsulant film further includes a second tie layer disposed between the secondary layer and the heat resistant layer. The second tie layer bonds the secondary layer to the heat resistant layer.

In some embodiments, the heat resistant layer defines an exterior surface of the encapsulant film.

In some embodiments, at least one of the encapsulating layer and the heat resistant layer is irradiated with a total irradiation dose of between 10 kilograys (kGy) to 200 kGy. Irradiating the encapsulating layer and/or the heat resistant layer may improve their heat resistance properties.

Another embodiment of the present disclosure is an encapsulant film for a photovoltaic module. The encapsulant film includes an encapsulating layer including polyethylene in an amount of 50% to 100%, by weight. The encapsulant film further includes a heat resistant layer disposed adjacent to the encapsulating layer. The heat resistant layer includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight. The encapsulant film further includes a first tie layer disposed between the encapsulating layer and the heat resistant layer. The first tie layer bonds the heat resistant layer to the encapsulating layer. The encapsulant film further includes a secondary layer disposed opposite to the encapsulating layer and adjacent to the heat resistant layer. The secondary layer includes polyethylene in an amount of 50% to 100%, by weight. The encapsulant film further includes a second tie layer disposed between the secondary layer and the heat resistant layer. The second tie layer bonds the secondary layer to the heat resistant layer.

Another embodiment of the present disclosure is a photovoltaic module. The photovoltaic module includes a photovoltaic layer. The photovoltaic module further includes a plurality of conductors disposed on the photovoltaic layer. The photovoltaic module further includes an encapsulant film. The encapsulant film includes an encapsulating layer encapsulating the plurality of conductors. The encapsulating layer includes polyethylene in an amount of 50% to 100%, by weight. The encapsulant film further includes a heat resistant layer disposed adjacent to the encapsulating layer. The heat resistant layer includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

In some embodiments, the photovoltaic module further includes a bulk encapsulant layer fully enclosing the photovoltaic layer and the encapsulant film.

In some embodiments, the encapsulant film is not coextensive with the photovoltaic layer, such that the encapsulant film partially covers the photovoltaic layer.

In some embodiments, the photovoltaic module further includes a front sheet and a back sheet disposed opposite to the front sheet. The photovoltaic layer is disposed between the front sheet and the back sheet. Each of the front sheet and the back sheet includes a glass or a polymer.

Another embodiment of the present disclosure is a method of manufacturing the photovoltaic module. The method includes providing the photovoltaic layer. The method further includes disposing the plurality of conductors on the photovoltaic layer. The method further includes laminating the encapsulant film on the photovoltaic layer, such that the encapsulating layer of the encapsulant film encapsulates the plurality of conductors.

There are several aspects of the present subject matter which may be embodied separately or together. These aspects may be employed alone or in combination with other aspects of the subject matter described herein, and the description of these aspects together is not intended to preclude the use of these aspects separately or the claiming of such aspects separately or in different combinations.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic cross-sectional view of a photovoltaic module in accordance with an embodiment of the present disclosure;

FIGS. 2A and 2B are cross-sectional views schematically depicting a method of manufacturing the photovoltaic module of FIG. 1 in accordance with an embodiment of the present disclosure;

FIG. 3 is a schematic cross-sectional view of an encapsulant film in accordance with an embodiment of the present disclosure;

FIG. 4 is a schematic cross-sectional view of an encapsulant film in accordance with another embodiment of the present disclosure; and

FIG. 5 is a schematic cross-sectional view of an encapsulant structure in accordance with an embodiment of the present disclosure.

The figures are not necessarily to scale. Like numbers used in the figures refer to like components. It will be understood, however, that the use of a number to refer to a component in a given figure is not intended to limit the component in another figure labeled with the same number.

### DETAILED DESCRIPTION

The present application describes an encapsulant film. The encapsulant film includes an encapsulating layer including polyethylene in an amount of 50% to 100%, by weight. The encapsulant film further includes a heat resistant layer disposed adjacent to the encapsulating layer. The heat resistant layer includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

During manufacture of the photovoltaic module, the encapsulating layer may bond to a plurality of conductors and to a photovoltaic layer of the photovoltaic module. Specifically, during lamination of the encapsulant film, the encapsulating layer may soften, flow, and form around the plurality of conductors.

The heat resistant layer may provide dimensional stability to the encapsulating layer during manufacture of the photovoltaic module and during operation of the photovoltaic module. Further, the heat resistant layer may prevent the plurality of conductors from burning through the encapsulant film during manufacture of the photovoltaic module and during operation of the photovoltaic module. The heat resistant layer may further provide additional properties to the encapsulant film, such as barrier properties, anti-corrosive properties, and the like.

As used herein, the terms “first” and “second” are used as identifiers. Therefore, such terms should not be construed as limiting of this disclosure. The terms “first” and “second” when used in conjunction with a feature or an element can be interchanged throughout the embodiments of this disclosure.

As used herein, the term “film” is a material with a very high ratio of a length or a width to a thickness. A film has two major surfaces defined by a length and a width. Films typically have good flexibility and can be used for a wide variety of applications. Films may also be of suitable thickness and/or material composition such that they are flexible, semi-rigid, or rigid. Films may be described as monolayer or multilayer.

As used herein, the terms “interior” and “exterior” refer to the major surfaces of a film or a layer.

As used herein, the term “tie layer” refers to a layer which has a primary function of bonding two adjacent layers together. The tie layers may be positioned between two layers of a multilayer film to maintain the two layers in position relative to each other and prevent undesirable delamination. Unless otherwise indicated, a tie layer can have any suitable composition that provides a desired level of adhesion with the one or more surfaces in contact with the tie layer material.

As used herein, the term “polyethylene” refers to a homopolymer or copolymer having at least one ethylene monomer linkage within the repeating backbone of the polymer. The ethylene linkage can be represented by the general formula: [CH₂—CH₂]ₙ. Polyethylenes may be formed by any method known to those skilled in the art.

As used herein, the terms “ethylene/vinyl alcohol copolymer” and “EVOH” both refer to polymerized ethylene vinyl alcohol. Ethylene/vinyl alcohol copolymers include saponified (or hydrolyzed) ethylene/vinyl acrylate copolymers and refer to a vinyl alcohol copolymer having an ethylene comonomer prepared by, for example, hydrolysis of vinyl acrylate copolymers or by chemical reactions with vinyl alcohol. The degree of hydrolysis is, preferably, at least 50% and, more preferably, at least 85%. Preferably, ethylene/vinyl alcohol copolymers include from about 28-48 mole % ethylene, more preferably, from about 32-44 mole % ethylene, and, even more preferably, from about 38-44 mole % ethylene.

As used herein, the terms “polymethyl methacrylate” and “PMMA” refer to a polymer containing methyl methacrylate (MMA) as a monomer. The IUPAC name of PMMA is poly(methyl 2-methylpropenoate).

As used herein, the terms “polymethyl pentene” and “PMP” refer to a polyolefin polymer whose main ingredient is 4-methyl pentene-1.

As used herein, the term “cycloolefin polymer” and “COP” refer to polymers obtained from a cyclic olefin, such as norbornene, tetracyclododecene, a derivative thereof, or the like.

As used herein, the term “cycloolefin copolymer” and “COC” refer to a copolymer composed of ethylene units and/or of units including an alpha olefin with a cyclic, bicyclic or multicyclic olefin.

As used herein, the terms “polylactic acid” and “PLA” refer to a polyester with the backbone formula (C₃H₄O₂)ₙ or [–C(CH₃)HC(=O)O–]ₙ. Polylactic acid may be obtained by condensation of lactic acid C(CH3)(OH)HCOOH with loss of water. Alternatively, polylactic acid may be prepared by ring-opening polymerization of lactide [–C(CH₃)HC(=O)O–]₂, the cyclic dimer of the basic repeating unit.

As used herein, the terms “polyethylene furanoate” and “PEF” refer to polyethylene 2,5-furandicarboxylate.

As used herein, the term “isosorbide polymer” refers to a polymer including isosorbide. Isosorbide polymer may be alternatively referred to as “isosorbide-based polymer”. Isosorbide polymer is a bio-based polymer. Isosorbide polymer may have a similar structure and/or a similar function as PMMA. An example of isosorbide polymer includes DURABIO™ available from Mitsubishi Chemical Corporation.

As used herein, the terms “polycarbonate” and “PC” refer to a polymer including the same or different carbonate units, or a copolymer that includes the same or different carbonate units, as well as one or more units other than carbonate (i.e., copolycarbonate).

As used herein, the terms “ethylene-vinyl acetate” and “EVA” refer to a copolymer of ethylene and vinyl acetate.

As used herein, the term “polyolefin” refers to a polymer with the general formula (CH₂CHR)ₙ, where R is an alkyl group.

As used herein, the term “extrusion” refers to the process of forming continuous shapes by forcing a molten plastic material through a die, followed by cooling or chemical hardening. The term "coextruded" refers to the process of extruding two or more materials through a single die with two or more orifices arranged so that the extrudates merge and weld together into a laminar structure before chilling (i.e., quenching).

As used herein, the term “modified” refers to a chemical derivative, e.g., one having any form of anhydride functionality, such as anhydride of maleic acid, crotonic acid, citraconic acid, itaconic acid, fumaric acid, etc., whether grafted onto a polymer, copolymerized with a polymer, or otherwise functionally associated with one or more polymers, and is also inclusive of derivatives of such functionalities, such as acids, esters, and metal salts derived therefrom. Another example of a common modification is acrylate modified polyolefins.

As used herein, the terms “melting temperature” and “Tm” refer to the temperature at which a solid and a liquid phase of a material may coexist in equilibrium.

As used herein, the terms “glass transition temperature” and “Tg” refer to the temperature at which the glass and liquid phases of an amorphous material exist in equilibrium, at any fixed pressure, and is the temperature that roughly defines the “knee” point of the material's density vs. temperature graph. The glass transition temperature of a semi-crystalline material is lower than its melting temperature.

As used herein, the term “adjacent” refers to being near, close, contiguous, adjoining, or neighboring in proximity. It includes, but is not limited to, being reasonably close to or in the vicinity of as well as touching, having a common boundary or having direct contact.

As used herein, the term “barrier property” refers to a property of a material or layer which controls a permeable element of a film, sheet, web, package, etc., against aggressive agents, and includes, but is not limited to, oxygen barrier, moisture (e.g., water, humidity, etc.) barrier, chemical barrier, and the like.

As used herein, the term “oxygen transmission rate” (OTR) is defined as an amount of oxygen that will pass through a material in a given time period. OTR is typically defined using units of cm³/m².day, or similar units, when measured at a defined temperature and humidity.

As used herein, the term “water vapor transmission rate” (WVTR) is defined as a steady state rate at which water vapor permeates through a film at specified conditions of temperature and relative humidity. WVTR is typically defined using units of g/m².day, or similar units, when measured at a defined temperature and humidity.

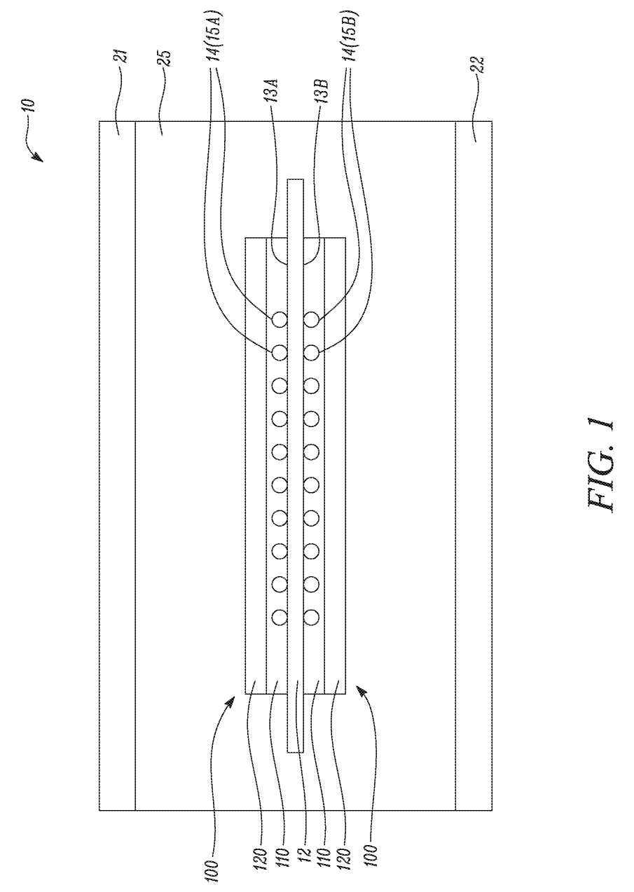

FIG. 1 shows a schematic cross-sectional view of a photovoltaic module 10 in accordance with an embodiment of the present disclosure.

Photovoltaic module 10 includes a photovoltaic layer 12. Photovoltaic layer 12 may be a semiconductor structure, for example, silicon(n⁺n(or p)p⁺). Photovoltaic layer 12 may be alternatively known as a solar cell layer or a semiconductor wafer.

Photovoltaic module 10 further includes a plurality of conductors 14 disposed on photovoltaic layer 12. Specifically, plurality of conductors 14 may be disposed on photovoltaic layer 12 in a parallel configuration with respect to each other. In the illustrated embodiment of FIG. 1, plurality of conductors 14 includes a set of first conductors 15A and a set of second conductors 15B disposed on opposing sides of photovoltaic layer 12. Specifically, in the illustrated embodiment of FIG. 1, set of first conductors 15A is disposed on a first major surface 13A of photovoltaic layer 12, and set of second conductors 15B is disposed on a second major surface 13B of photovoltaic layer 12 that is opposite to first major surface 13A.

Further, each of plurality of conductors 14 may be disposed in direct contact with photovoltaic layer 12. Each of the plurality of conductors 14 may include a metallic wire coated with a coating. The coating may include an alloy having a low melting point. In some embodiments, the metallic wire may be completely coated with an alloy coating or only partly coated on the side or sides contacting the surface (i.e., first major surface 13A or second major surface 13B) of photovoltaic layer 12.

Photovoltaic module 10 further includes an encapsulant film 100. Encapsulant film 100 includes an encapsulating layer 110 and a heat resistant layer 120 disposed adjacent to encapsulating layer 110.

As shown in FIG. 1, encapsulating layer 110 encapsulates the plurality of conductors 14. Encapsulating layer 110 may encapsulate and secure the plurality of conductors 14 on photovoltaic layer 12. In the illustrated embodiment of FIG. 1, photovoltaic module 10 includes a pair of encapsulant films 100 disposed on the opposing sides of photovoltaic layer 12. Further, encapsulating layer 110 of one pair of encapsulant films 100 encapsulates set of first conductors 15A, and encapsulating layer 110 of the other pair of encapsulant films 100 encapsulates set of second conductors 15B.

In some embodiments, encapsulant film 100 is not coextensive with photovoltaic layer 12, such that encapsulant film 100 partially covers photovoltaic layer 12. In other words, encapsulant film 100 may have smaller dimensions as compared to photovoltaic layer 12. Encapsulant film 100 may not entirely cover the major surface 13A,13B of the photovoltaic layer 12. Portions of the major surfaces 13A,13B photovoltaic layer 12 may not have direct contact with either the plurality of conductors 14 or the encapsulant films 100.

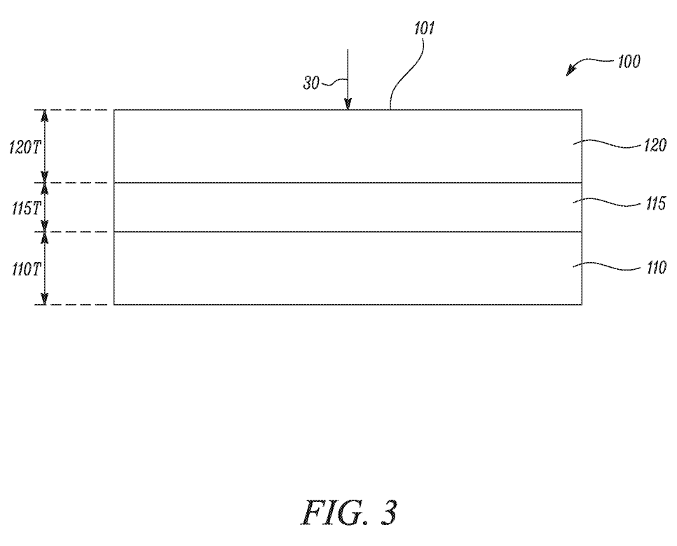

In the illustrated embodiment of FIG. 1, one of pair of encapsulant films 100 fully covers the set of first conductors 15A and the other of pair of encapsulant films 100 fully covers the set of second conductors 15B. Further, each of pair of encapsulant films 100 partially covers photovoltaic layer 12. Encapsulant film 100 will be described in detail later with reference to FIG. 3.

In some embodiments, photovoltaic module 10 further includes a front sheet 21 and a back sheet 22 disposed opposite to front sheet 21. Specifically, photovoltaic layer 12 may be disposed between front sheet 21 and back sheet 22. In some embodiments, each of front sheet 21 and back sheet 22 includes a glass or a polymer.

In some embodiments, photovoltaic module 10 further includes a bulk encapsulant layer 25 fully enclosing photovoltaic layer 12 and encapsulant films 100. Specifically, bulk encapsulant layer 25 may be disposed between front sheet 21 and back sheet 22, such that bulk encapsulant layer 25 fully encloses photovoltaic layer 12 and encapsulant films 100. In some embodiments, bulk encapsulant layer 25 may include ethylene-vinyl acetate (EVA) or polyolefin elastomers (POE).

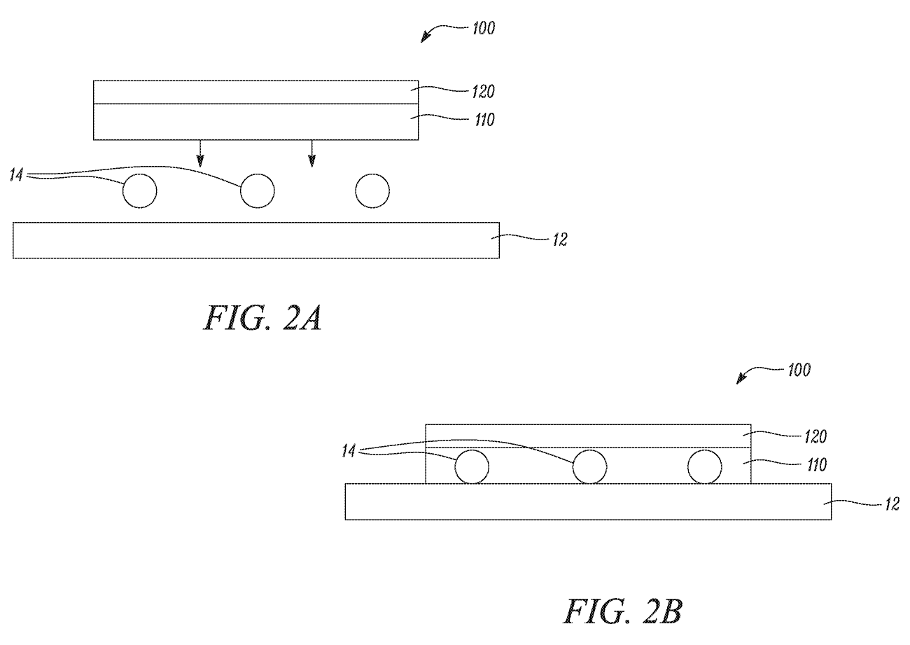

FIGS. 2A and 2B schematically show a method of manufacturing photovoltaic module 10 of FIG. 1 in accordance with an embodiment of the present disclosure.

Referring to FIGS. 1, 2A, and 2B, the method includes providing photovoltaic layer 12. The method further includes disposing a plurality of conductors 14 on photovoltaic layer 12. Plurality of conductors 14 may be disposed in direct contact with photovoltaic layer 12. In some embodiments, as shown in FIG. 1, the method may include disposing sets of first and second conductors 15A, 15B on opposing sides of photovoltaic layer 12.

The method further includes laminating encapsulant film 100 on photovoltaic layer 12, such that encapsulating layer 110 of the encapsulant film 100 encapsulates the plurality of conductors 14. In some embodiments, as shown in FIG. 1, the method may include laminating a first set of conductors 15A on first major surface 13A of photovoltaic layer 12 with one of pair of encapsulant films 100, and a second set of conductors 15B on second major surface 13B of photovoltaic layer 12 with the other of pair of encapsulant films 100. It may be noted that encapsulant film 100 may be laminated on photovoltaic layer 12 by any suitable lamination process. In some embodiments, encapsulant film 100 may be laminated on photovoltaic layer 12 by vacuum lamination.

Although not illustrated in FIGS. 2A and 2B, the method may further include disposing photovoltaic layer 12 and encapsulant film 100 between front sheet 21 and back sheet 22. The method may further include providing bulk encapsulant layer 25, such that bulk encapsulant layer 25 fully encloses photovoltaic layer 12 and encapsulant film 100. Bulk encapsulant layer 25 may be provided in a liquid or a semi-liquid state.

During manufacture of photovoltaic module 10, encapsulant film 100 may be brought into contact with the plurality of conductors 14 with heat and pressure. This may cause encapsulating layer 110 to soften, flow, and form around plurality of conductors 14. Encapsulating layer 110 may therefore bond to the plurality of conductors 14 and to photovoltaic layer 12.

Heat resistant layer 120 may offer a high stiffness, for example, due to a high melting temperature and/or a high glass transition temperature thereof. As a result, heat resistant layer 120 may provide dimensional stability to encapsulating layer 110 (which may have a low melting temperature and/or a low glass transition temperature), thereby stabilizing the plurality of conductors 14 during lamination. Specifically, heat resistant layer 120 may provide dimensional stability to encapsulating layer 110 (when encapsulating layer 110 may be in a glassy state during manufacture of photovoltaic module 10), thereby stabilizing the plurality of conductors 14 and isolating the plurality of conductors 14 from forces (e.g., shear forces) originating due to bulk encapsulant layer 25, for instance, during vacuum lamination process. Therefore, encapsulant film 100 may provide a reliable bonding of plurality of conductors 14 to photovoltaic layer 12. Further, heat resistant layer 120 may prevent the plurality of conductors 14 from burning through encapsulant film 100 during manufacture of photovoltaic module 10 and during operation of photovoltaic module 10.

FIG. 3 shows a schematic cross-sectional view of the encapsulant film 100 in accordance with an embodiment of the present disclosure.

Encapsulating layer 110 includes polyethylene in an amount of 50% to 100%, by weight. In some embodiments, encapsulating layer 110 may include polyethylene in an amount of about 70%, about 80%, about 90%, or about 95%. In some embodiments, encapsulating layer 110 may include only polyethylene (i.e., 100% polyethylene).

In some embodiments, the polyethylene of encapsulating layer 110 includes at least one of ultra-low-density polyethylene, low density polyethylene, linear low-density polyethylene, medium density polyethylene, linear medium density polyethylene, metallocene low density polyethylene, high density polyethylene, ethylene vinyl acetate, ethylene acrylate, ethylene acrylic acid, and methacrylic acid copolymer.

Furthermore, in some embodiments, the polyethylene of encapsulating layer 110 is modified with one of maleic anhydride, carboxylic acid, methacrylic acid, acrylic acid, acrylate, and glycidyl methacrylate in an amount of 0.01% to 9%, by weight of encapsulating layer 110. Modification of the polyethylene of encapsulating layer 110 may improve, for example, flow and/or adhesion characteristics of encapsulating layer 110 upon being heated.

Encapsulating layer 110 includes a thickness 110T. Thickness 110T of encapsulating layer 110 may be an average thickness of encapsulating layer 110. In some embodiments, thickness 110T is from 5 microns to 100 microns. In some embodiments, thickness 110T may be about 10 microns, about 20 microns, about 30 microns, about 40 microns, about 50 microns, about 60 microns, about 70 microns, about 80 microns, or about 90 microns.

Encapsulant film 100 further includes heat resistant layer 120. Heat resistant layer 120 includes one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

In the illustrated embodiment of FIG. 3, encapsulant film 100 further includes a first tie layer 115 disposed between encapsulating layer 110 and heat resistant layer 120. First tie layer 115 bonds heat resistant layer 120 to encapsulating layer 110. However, it may be noted that first tie layer 115 is optional and may be omitted from encapsulant film 100, in which case encapsulating layer 110 is disposed adjacent to heat resistant layer 120.

First tie layer 115 may include polyethylene in an amount of 50% to 100%, by weight. In some embodiments, the polyethylene of first tie layer 115 may be modified with maleic anhydride (MAH) in an amount of 0.01% to 9%, by weight of first tie layer 115. In one example, first tie layer 115 may include maleic anhydride modified low-density polyethylene.

Further, first tie layer 115 may include a thickness 115T. Thickness 115T of first tie layer 115 may be an average thickness of first tie layer 115. In some embodiments, thickness 115T of first tie layer 115 may be from 2 microns to 6 microns.

As discussed above, heat resistant layer 120 may offer a high stiffness, for example, due to a high melting temperature and/or a high glass transition temperature thereof. Specifically, in some embodiments, heat resistant layer 120 includes a glass transition temperature (Tg) of more than 85 °C, and preferably more than 140 °C. Such high glass transition temperature may enable heat resistant layer 120 including amorphous polymers (such as PMMA) to provide high stiffness and dimensional stability to encapsulating layer 110 during lamination with photovoltaic module 10 (shown in FIG. 1) and during operation of photovoltaic module 10.

In some other embodiments, heat resistant layer 120 includes a glass transition temperature (Tg) of more than 20 °C, and further includes a melting temperature (Tm) of more than 85 °C, and preferably more than 140 °C. Such combination of glass transition temperature and high melting temperature may enable heat resistant layer 120 including semi-crystalline polymers (such as EVOH) to provide high stiffness and dimensional stability to encapsulating layer 110 during lamination with photovoltaic module 10 (shown in FIG. 1) and during operation of photovoltaic module 10.

Heat resistant layer 120 includes a thickness 120T. Thickness 120T of heat resistant layer 120 may be an average thickness of heat resistant layer 120. In some embodiments, thickness 120T of heat resistant layer 120 is from 1.5 microns to 30 microns. In some embodiments, thickness 120T may be about 5 microns, about 10 microns, about 15 microns, about 20 microns, or about 25 microns.

Encapsulating film 100 may need to be substantially transparent to incident light having an ultraviolet (UV) wavelength, a visible wavelength, and an infrared (IR) wavelength to prevent an undesirable loss of efficiency of photovoltaic module 10 (shown in FIG. 1). In other words, encapsulating film 100 may need to be UV transparent, visible light transparent, and IR transparent in order to facilitate operational efficiency of photovoltaic module 10. To this end, in some embodiments, for an incident light 30 having a wavelength greater than 280 nanometers (nm), encapsulating film 100 transmits at least 80% of incident light 30. In some embodiments, for incident light 30 having a wavelength greater than 280 nm, encapsulating film 100 may transmit at least 90% of incident light 30. Specifically, in the illustrated embodiment of FIG. 3, for incident light 30 having a wavelength greater than 280 nm, encapsulating layer 110, first tie layer 115, and heat resistant layer 120 may together transmit at least 80%, and preferably at least 90% of incident light 30.

In some embodiments, at least one of encapsulating layer 110 and heat resistant layer 120 is irradiated with a total irradiation dose of between 10 kilograys (kGy) to 200 kGy. Irradiation of at least one of encapsulating layer 110 and heat resistant layer 120 may be carried out by electron beam curing. Irradiating encapsulating layer 110 and/or heat resistant layer 120 may improve their heat resistance properties.

Heat resistant layer 120 may further provide various additional properties (e.g., barrier properties, UV resistance, corrosion resistance) to encapsulant film 100. Specifically, heat resistant layer 120 improve resistance against potential induced degradation (PID), protection against corrosion due to, for example, acetic acid or other corrosive compounds, and provide barrier properties (e.g., reduced Water Vapor Transmission Rate (WVTR) and reduced Oxygen Transmission Rate (OTR)) to encapsulant film 100.

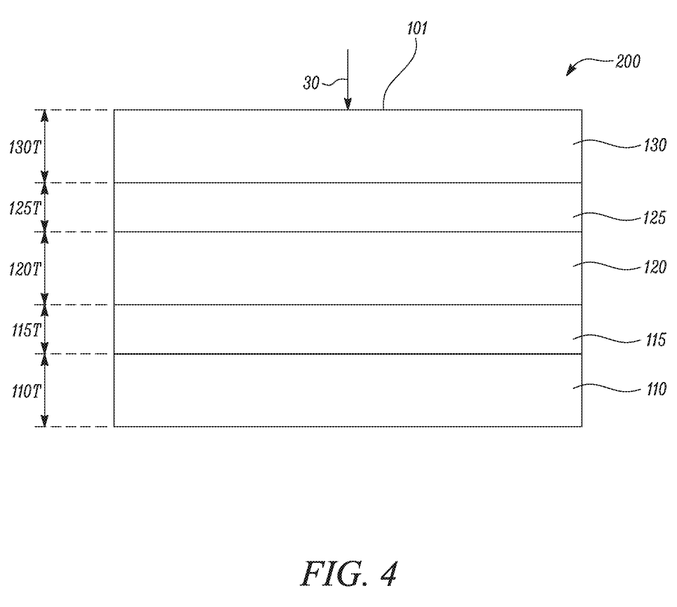

In the illustrated embodiment of FIG. 3, heat resistant layer 120 defines an exterior surface 101 of encapsulant film 100. However, in some other embodiments, encapsulant film 100 may include additional layers that define exterior surface 101. Examples of such additional layers will be described hereinafter with reference to FIG. 4.

FIG. 4 shows a schematic cross-sectional view of an encapsulant film 200 in accordance with another embodiment of the present disclosure. Components of encapsulant film 200 that are similar to components of encapsulant film 100 of FIG. 3 are designated by like reference characters.

In the illustrated embodiment of FIG. 4, encapsulant film 200 further includes a secondary layer 130 disposed opposite to encapsulating layer 110. Heat resistant layer 120 is disposed between secondary layer 130 and encapsulant layer 110. Further, in the illustrated embodiment of FIG. 4, secondary layer 130 defines exterior surface 101 of encapsulant film 200.

In some embodiments, secondary layer 130 includes polyethylene in an amount of 50% to 100%, by weight. In some embodiments, the polyethylene of secondary layer 130 may include at least one of ultra-low-density polyethylene, low density polyethylene, linear low-density polyethylene, medium density polyethylene, linear medium density polyethylene, metallocene low density polyethylene, high density polyethylene, ethylene vinyl acetate, ethylene acrylate, ethylene acrylic acid, and methacrylic acid copolymer.

Further, in some embodiments, the polyethylene of secondary layer 130 is modified with one of maleic anhydride, carboxylic acid, methacrylic acid, acrylic acid, acrylate, and glycidyl methacrylate in an amount of 0.01% to 9%, by weight of secondary layer 130.

Secondary layer 130 may act as a primer and improve adhesion of bulk encapsulant layer 25 (shown in FIG. 1) with encapsulant film 200. In some embodiments, secondary layer 130 may be irradiated with a total irradiation dose of between 10 kilograys (kGy) to 200 kGy.

Secondary layer 130 includes a thickness 130T. Thickness 130T of secondary layer 130 may be an average thickness of secondary layer 130. In some embodiments, thickness 130T is from 5 microns to 100 microns. In some embodiments, thickness 130T may be about 10 microns, about 20 microns, about 30 microns, about 40 microns, about 50 microns, about 60 microns, about 70 microns, about 80 microns, or about 90 microns.

In the illustrated embodiment of FIG. 4, encapsulant film 200 further includes a second tie layer 125 disposed between secondary layer 130 and heat resistant layer 120. Second tie layer 125 bonds secondary layer 130 to heat resistant layer 120.

Second tie layer 125 may include polyethylene in an amount of 50% to 100%, by weight. In some embodiments, the polyethylene of second tie layer 125 may be modified with maleic anhydride (MAH) in an amount of 0.01% to 9%, by weight of second tie layer 125. In one example, second tie layer 125 may include maleic anhydride modified low-density polyethylene.

Further, second tie layer 125 may include a thickness 125T. Thickness 125T of second tie layer 125 may be an average thickness of second tie layer 125. In some embodiments, thickness 125T of second tie layer 125 may be from 2 microns to 6 microns.

In some embodiments, for incident light 30 having a wavelength greater than 280 nm, encapsulating film 200 transmits at least 80% of incident light 30. In some embodiments, for incident light 30 having a wavelength greater than 280 nm, encapsulating film 200 may transmit at least 90% of incident light 30. Specifically, in the illustrated embodiment of FIG. 4, for incident light 30 having a wavelength greater than 280 nm, encapsulating layer 110, first tie layer 115, heat resistant layer 120, second tie layer 125, and secondary layer 130 together may transmit at least 80%, and preferably at least 90% of incident light 30.

Further, encapsulating layer 110, heat resistant layer 120, and secondary layer 130 may provide a symmetrical structure to encapsulant film 200. The symmetrical structure may reduce or prevent curling of the encapsulant film 200, thereby facilitating processing of the encapsulant film 200. Further, the stiffness provided by heat resistant layer 120 may facilitate handling of encapsulant film 200 during a roll-to-roll process.

Moreover, in some embodiments, encapsulating layer 110, heat resistant layer 120, and secondary layer 130 are coextruded together. In some embodiments, secondary layer 130, second tie layer 125, heat resistant layer 120, first tie layer 115, and encapsulating layer 110 are coextruded with each other and positioned relative to each other in a sequential order.

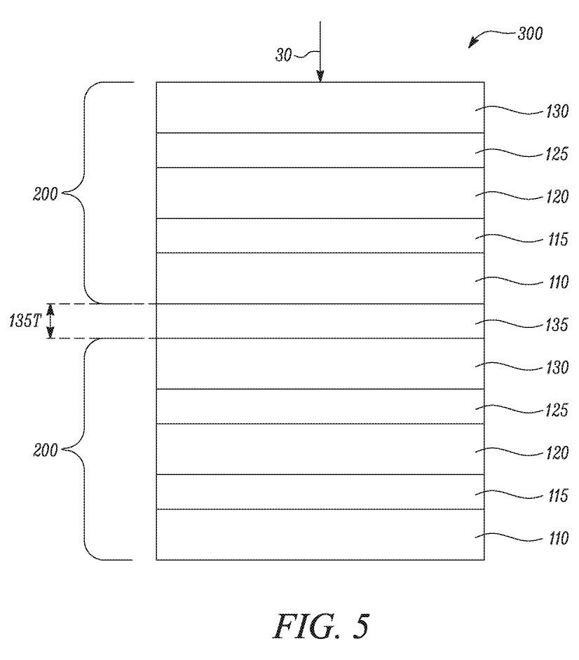

FIG. 5 illustrates an encapsulant structure 300 in accordance with an embodiment of the present disclosure.

Encapsulant structure 300 includes a plurality of encapsulant films 200 of FIG. 4 disposed adjacent to each other. Specifically, encapsulating layer 110 of one encapsulant film 200 from a plurality of encapsulating films 200 is disposed adjacent to secondary layer 130 of an adjacent encapsulant film 200 from the plurality of encapsulating films 200.

Further, encapsulant structure 300 may optionally include a third tie layer 135 disposed between two adjacent encapsulant films 200 from the plurality of encapsulating films 200. Third tie layer 135 may bond two adjacent encapsulant films 200 to each other. Third tie layer 135 may include polyethylene in an amount of 50% to 100%, by weight. In some embodiments, the polyethylene of third tie layer 135 may be modified with maleic anhydride (MAH) in an amount of 0.01% to 9%, by weight of third tie layer 135. In one example, third tie layer 135 may include maleic anhydride modified low-density polyethylene. Further, third tie layer 135 may include a thickness 135T. Thickness 135T of third tie layer 135 may be an average thickness of third tie layer 135. In some embodiments, thickness 135T of third tie layer 135 may be from 2 microns to 6 microns.

In similar embodiments to encapsulant structure 300, a structure may include two encapsulant films 200 oriented adjacent to one another, where in the secondary layers 130 are coextruded adjacent to one another via collapsed bubble coextrusion creating an overall symmetrical structure.

In some embodiments, for incident light 30 having a wavelength greater than 280 nm, encapsulant structure 300 may transmit at least 80% of incident light 30. In some embodiments, for incident light 30 having a wavelength greater than 280 nm, encapsulating structure 300 may transmit at least 90% of incident light 30.

Referring to FIGS. 1 and 5, due to presence of multiple heat resistant layers 120, encapsulant structure 300 may further improve stabilization of plurality of conductors 14 and isolation of plurality of conductors 14 from forces (e.g., shear forces) originating due to bulk encapsulant layer 25.

Each and every document cited in this present application, including any cross referenced, is incorporated in this present application in its entirety by this reference, unless expressly excluded or otherwise limited. The citation of any document is not an admission that it is prior art with respect to any embodiment disclosed in this present application or that it alone, or in any combination with any other reference or references, teaches, suggests, or discloses any such embodiment. Further, to the extent that any meaning or definition of a term in this present application conflicts with any meaning or definition of the same term in a document incorporated by reference, the meaning or definition assigned to that term in this present application governs.

Unless otherwise indicated, all numbers expressing sizes, amounts, ranges, limits, and physical and other properties used in the present application are to be understood as being preceded in all instances ay the term “about”. Accordingly, unless expressly indicated to the contrary, the numerical parameters set forth in the present application are approximations that can vary depending on the desired properties sought to be obtained by a person of ordinary skill in the art without undue experimentation using the teachings disclosed in the present application.

As used in the present application, the singular forms “a”, “an”, and “the” encompass embodiments having plural referents, unless the context clearly dictates otherwise. As used in the present application, the term “or” is generally employed in its sense including “and/or”, “unless” the context clearly dictates otherwise.

Spatially related terms, including but not limited to, “lower”, “upper”, “beneath”, “below”, “above”, “bottom” and “top”, if used in the present application, are used for ease of description to describe spatial relationships of an element(s) to another. Such spatially related terms encompass different orientations of the device in use or operation, in addition to the particular orientations depicted in the figures and described in the present application. For example, if an object depicted in the drawings is turned over or flipped over, elements previously described as below, or beneath other elements would then be above those other elements.

The drawings show some but not all embodiments. The elements depicted in the drawings are illustrative and not necessarily to scale, and the same (or similar) reference numbers denote the same (or similar) features throughout the drawings.

The description, examples, embodiments, and drawings disclosed are illustrative only and should not be interpreted as limiting. The present disclosure includes the description, examples, embodiments, and drawings disclosed; but it is not limited to such description, examples, embodiments, or drawings. As briefly described above, the reader should assume that features of one disclosed embodiment can also be applied to all other disclosed embodiments, unless expressly indicated to the contrary. Modifications and other embodiments will be apparent to a person of ordinary skill in the packaging arts, and all such modifications and other embodiments are intended and deemed to be within the scope of the present disclosure.

### ENCAPSULANT FILM EMBODIMENTS

A. An encapsulant film for a photovoltaic module, the encapsulant film comprising:

an encapsulating layer comprising polyethylene in an amount of 50% to 100%, by weight; and

a heat resistant layer disposed adjacent to the encapsulating layer, the heat resistant layer comprising one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

B. The encapsulant film according to Embodiment A, wherein the polyethylene of the encapsulating layer is modified with one of maleic anhydride, carboxylic acid, methacrylic acid, acrylic acid, acrylate, and glycidyl methacrylate in an amount of 0.01% to 9%, by weight of the encapsulating layer.

C. The encapsulant film according to any previous Embodiment, wherein the polyethylene of the encapsulating layer comprises at least one of ultra-low-density polyethylene, low density polyethylene, linear low-density polyethylene, medium density polyethylene, linear medium density polyethylene, metallocene low density polyethylene, high density polyethylene, ethylene vinyl acetate, ethylene acrylate, ethylene acrylic acid, and methacrylic acid copolymer.

D. The encapsulant film according to any previous Embodiment, wherein the encapsulating layer comprises a thickness from 5 microns to 100 microns.

E. The encapsulant film according to any previous Embodiment, wherein the heat resistant layer comprises a thickness from 1.5 microns to 30 microns.

F. The encapsulant film according to any previous Embodiment, wherein the heat resistant layer comprises a glass transition temperature (Tg) of more than 85 °C, and preferably more than 140°C.

G. The encapsulant film according to any previous Embodiment, wherein the heat resistant layer comprises a glass transition temperature (Tg) of more than 20 °C, and wherein the heat resistant layer further comprises a melting temperature (Tm) of more than 85 °C, and preferably more than 140°C.

H. The encapsulant film according to any previous Embodiment, wherein for an incident light having a wavelength greater than 300 nanometers, the encapsulant film transmits at least 50% of the incident light, and more preferably at least 75%.

I. The encapsulant film according to any previous Embodiment, further comprising a first tie layer disposed between the encapsulating layer and the heat resistant layer, wherein the first tie layer bonds the heat resistant layer to the encapsulating layer.

J. The encapsulant film according to any other Embodiment, further comprising a secondary layer disposed opposite to the encapsulating layer and adjacent to the heat resistant layer, the secondary layer comprising polyethylene in an amount of 50% to 100%, by weight.

K. The encapsulant film according to Embodiment J, wherein the polyethylene of the secondary layer is modified with one of maleic anhydride, carboxylic acid, methacrylic acid, acrylic acid, acrylate, and glycidyl methacrylate in an amount of 0.01% to 9%, by weight of the secondary layer.

L. The encapsulant film according to Embodiment J or K, wherein the secondary layer comprises a thickness from 5 microns to 100 microns.

M. The encapsulant film according to any of Embodiments J through L, wherein the encapsulating layer, the heat resistant layer, and the secondary layer are coextruded together.

N. The encapsulant film according to any of Embodiments J through M, further comprising a second tie layer disposed between the secondary layer and the heat resistant layer, wherein the second tie layer bonds the secondary layer to the heat resistant layer.

O. The encapsulant film according to any previous Embodiment, wherein the heat resistant layer defines an exterior surface of the encapsulant film.

P. The encapsulant film according to any previous Embodiment, wherein at least one of the encapsulating layer and the heat resistant layer is irradiated with a total irradiation dose of between 10 kilograys (kGy) to 200 kGy.

Q. An encapsulant film for a photovoltaic module, the encapsulant film comprising:

an encapsulating layer comprising polyethylene in an amount of 50% to 100%, by weight;

a heat resistant layer disposed adjacent to the encapsulating layer, the heat resistant layer comprising one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight;

a first tie layer disposed between the encapsulating layer and the heat resistant layer, wherein the first tie layer bonds the heat resistant layer to the encapsulating layer;

a secondary layer disposed opposite to the encapsulating layer and adjacent to the heat resistant layer, the secondary layer comprising polyethylene in an amount of 50% to 100%, by weight; and

a second tie layer disposed between the secondary layer and the heat resistant layer, wherein the second tie layer bonds the secondary layer to the heat resistant layer.

### PHOTOVOLTAIC MODULE EMBODIMENTS

R. A photovoltaic module comprising:

a photovoltaic layer;

a plurality of conductors disposed on the photovoltaic layer; and

an encapsulant film comprising:

an encapsulating layer encapsulating the plurality of conductors, the encapsulating layer comprising polyethylene in an amount of 50% to 100%, by weight; and

a heat resistant layer disposed adjacent to the encapsulating layer, the heat resistant layer comprising one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

S. The photovoltaic module according to Embodiment R, further comprising a bulk encapsulant layer fully enclosing the photovoltaic layer and the encapsulant film.

T. The photovoltaic module according to Embodiment R or Embodiment S, wherein the encapsulant film is not coextensive with the photovoltaic layer, such that the encapsulant film partially covers the photovoltaic layer.

U. The photovoltaic module according to any of Embodiments R through T, further comprising a front sheet and a back sheet disposed opposite to the front sheet, wherein the photovoltaic layer is disposed between the front sheet and the back sheet, and wherein each of the front sheet and the back sheet comprises a glass or a polymer.

V. A method of manufacturing the photovoltaic module according any of Embodiments R through U, the method comprising:

providing the photovoltaic layer;

disposing the plurality of conductors on the photovoltaic layer; and

laminating the encapsulant film on the photovoltaic layer, such that the encapsulating layer of the encapsulant film encapsulates the plurality of conductors.

What is claimed is:

1. A photovoltaic module comprising:
a photovoltaic layer;
a plurality of conductors disposed on the photovoltaic layer; and
an encapsulant film comprising:
an encapsulating layer encapsulating the plurality of conductors, the encapsulating layer comprising polyethylene in an amount of 50% to 100%, by weight; and
a heat resistant layer disposed adjacent to the encapsulating layer, the heat resistant layer comprising one of ethylene vinyl alcohol (EVOH), polymethyl methacrylate (PMMA), polymethyl pentene (PMP), cycloolefin polymer (COP), cycloolefin copolymer (COC), polylactic acid (PLA), polyethylene furanoate (PEF), isosorbide polymer, and polycarbonate (PC) in an amount of 50% to 100%, by weight.

2. The photovoltaic module according to claim 1, further comprising a bulk encapsulant layer fully enclosing the photovoltaic layer and the encapsulant film.

3. The photovoltaic module according to claim 1, wherein the encapsulant film is not coextensive with the photovoltaic layer, such that the encapsulant film partially covers the photovoltaic layer.

4. The photovoltaic module according to claim 1, further comprising a front sheet and a back sheet disposed opposite to the front sheet, wherein the photovoltaic layer is disposed between the front sheet and the back sheet, and wherein each of the front sheet and the back sheet comprises a glass or a polymer.

5. The photovoltaic module according to claim 1, wherein the polyethylene of the encapsulating layer is modified with one of maleic anhydride, carboxylic acid, methacrylic acid, acrylic acid, acrylate, and glycidyl methacrylate in an amount of 0.01% to 9%, by weight of the encapsulating layer.

6. The photovoltaic module according to claim 1, wherein the polyethylene of the encapsulating layer comprises at least one of ultra-low-density polyethylene, low density polyethylene, linear low-density polyethylene, medium density polyethylene, linear medium density polyethylene, metallocene low density polyethylene, high density polyethylene, ethylene vinyl acetate, ethylene acrylate, ethylene acrylic acid, and methacrylic acid copolymer.

7. The photovoltaic module according to claim 1, wherein the encapsulating layer comprises a thickness from 5 microns to 100 microns.

8. The photovoltaic module according to claim 1, wherein the heat resistant layer comprises a thickness from 1.5 microns to 30 microns.

9. The photovoltaic module according to claim 1, wherein the heat resistant layer comprises a glass transition temperature (Tg) of more than 85 °C.

10. The photovoltaic module according to claim 1, wherein the heat resistant layer comprises a glass transition temperature (Tg) of more than 20 °C, and wherein the heat resistant layer further comprises a melting temperature (Tm) of more than 85 °C.

11. The photovoltaic module according to claim 1, wherein for an incident light having a wavelength greater than 300 nanometers, the encapsulant film transmits at least 50% of the incident light.

12. The photovoltaic module according to claim 1, further comprising a first tie layer disposed between the encapsulating layer and the heat resistant layer, wherein the first tie layer bonds the heat resistant layer to the encapsulating layer.

13. The photovoltaic module according to claim 1, further comprising a secondary layer disposed opposite to the encapsulating layer and adjacent to the heat resistant layer, the secondary layer comprising polyethylene in an amount of 50% to 100%, by weight.

14. The photovoltaic module according to claim 13, wherein the polyethylene of the secondary layer is modified with one of maleic anhydride, carboxylic acid, methacrylic acid, acrylic acid, acrylate, and glycidyl methacrylate in an amount of 0.01% to 9%, by weight of the secondary layer.

15. The photovoltaic module according to claim 13, wherein the secondary layer comprises a thickness from 5 microns to 100 microns.

16. The photovoltaic module according to claim 13, wherein the encapsulating layer, the heat resistant layer, and the secondary layer are coextruded together.

17. The photovoltaic module according to claim 13, further comprising a second tie layer disposed between the secondary layer and the heat resistant layer, wherein the second tie layer bonds the secondary layer to the heat resistant layer.

18. The photovoltaic module according to claim 1, wherein the heat resistant layer defines an exterior surface of the encapsulant film.

19. The photovoltaic module according to claim 1, wherein at least one of the encapsulating layer and the heat resistant layer is irradiated with a total irradiation dose of between 10 kilograys (kGy) to 200 kGy.

20. A method of manufacturing the photovoltaic module according to claim 1, the method comprising:
providing the photovoltaic layer;
disposing the plurality of conductors on the photovoltaic layer; and
laminating the encapsulant film on the photovoltaic layer, such that the encapsulating layer of the encapsulant film encapsulates the plurality of conductors.
